(19) United States
(12) Patent Application Publication
(10) Pub. No.: US 2024/0235695 A1
(43) Pub. Date: Jul. 11, 2024

(54) VERSATILE RF CONTROL SYSTEM FOR MANIPULATING OPTICAL SIGNALS, AN OPTICAL ARRANGEMENT OF SUCH A VERSATILE RF CONTROL SYSTEM AND AN OPTICAL SYSTEM AND A MEASURING DEVICE WITH SUCH AN OPTICAL ARRANGEMENT

(71) Applicant: Rohde & Schwarz GmbH & Co. KG, Munchen (DE)

(72) Inventor: Julius SEEGER, Prien am Chiemsee (DE)

(21) Appl. No.: 18/524,438

(22) Filed: Nov. 30, 2023

(30) Foreign Application Priority Data
Dec. 4, 2022 (DE) DE102022132120

(51) Int. Cl. H04B 10/70

(52) U.S. Cl. CPC H04B 10/70

(57) ABSTRACT

A versatile RF control system (1) is used for generating an RF signal (2) for manipulating optical signals (73) or for controlling quantum systems. The RF signal (2) can be adjusted by the versatile RF control system (1) in frequency, phase and amplitude in further ranges according to a user specification. This also includes modulations of the RF signal (2) in order to be able to imprint the properties of the RF signal (2) on an optical signal (73), for example. The versatile RF control system (1) can be operated in a controlled mode (first operating mode) and in a static (uncontrolled) mode (second operating mode). In controlled mode, modulation errors on the (optical) transmission path (75) can be compensated. In uncontrolled mode, modulation errors in the (optical) transmission path (75) can be detected. Due to the modular design, any number of RF signals (2) can be generated independently of each other.

The disclosure relates to a versatile RF control system for manipulating optical signals, an optical arrangement of such a versatile RF control system and an optical system, and a measuring device with such an optical arrangement.

In many setups for the investigation of quantum phenomena, quantum systems and also the operation of some types of quantum computers, in particular those realized with ultracold atoms or ions, there is a need for arbitrarily modulatable signal sources in order to perform the necessary manipulations of the quantum states.

To this end, signal sources in the RF and optical range are used. Typically, optical signals are not modulated directly at the optical signal source. Instead, RF signal sources and unmodulated, fixed-frequency optical sources are used and the RF signals are modulated onto the optical signal using a modulator (acousto-optical modulators, electro-optical modulators).

Due to the complex structure of such equipment, the signals are typically transported to the point of use over longer signal paths and are subject to various effects along the signal path that reduce signal integrity. For example, the power of the modulated signals often fluctuates due to temperature fluctuations in the crystalline media used for modulation or due to thermal drift effects. In fiber couplers, which are used to couple the optical signals into optical fibers. During the signal propagation of the modulated signals in an optical fiber, the phase and frequency of the signal is changed by linear and non-linear effects due to temperature and pressure fluctuations.

Subsequent compensation or subsequent offsetting of modulation errors is not possible when using modulated signals in quantum applications, as the quantum system has already interacted with the signal and information read back from the quantum system may be corrupted.

Active control systems are therefore required that allow the various modulation parameters of a single signal to be stabilized. An important prerequisite for their use is that the various modulation parameters can typically only be measured at different points in an apparatus. In addition, a high degree of flexibility is necessary in order to meet changing requirements when operating quantum-based measuring equipment or quantum computers.

A very compact design with as few external components as possible is therefore necessary, in particular to promote the scalability of quantum systems for commercial applications such as quantum computing.

It is therefore the task of the present disclosure to provide a very compact structure with as few external components as possible in order to be able to generate the necessary modulatable signals.

The task is solved by the versatile RF control system according to claim 1, as well as by an optical arrangement of a versatile RF control system and an optical system according to claim 31, as well as by a measuring device with such an optical arrangement according to claim 35. Claims 2 to 30 contain further embodiments of the versatile RF control system. Claims 32 to 34 contain further embodiments of the optical arrangement.

In particular, the present disclosure provides a solution as to how an arbitrarily modulatable signal (and also several signals relative to each other) can be specifically adjusted in all its modulation parameters and can also be stabilized by mutually independent control loops. The described arrangement with as few external interfaces as possible allows the user a flexible and easily scalable solution to ensure signal integrity in complex quantum systems and their control architectures.

The versatile RF control system according to the disclosure comprises a central control module and at least one module group. The at least one module group can be used to generate an RF signal, which can be used to manipulate optical signals, in particular to control quantum systems. The at least one module group comprises an RF generation module, a reference signal generation module and a control module.

The central control module is configured to receive parameters for the RF signal to be generated by the at least one module group. In particular, these parameters may be specifications for the frequency, the phase and/or the amplitude of the RF signal to be generated. The central control module is configured to use the received parameters to generate control variables for the RF generation module of the at least one module group and to transmit them to the RF generation module of the at least one module group. The control variable can, for example, be a frequency word for a DDS. The central control module is also configured to use the received parameters to generate control variables for the reference signal generation module of the at least one module group and to transmit them to the reference signal generation module of the at least one module group. In this case, the control variable can, for example, be a time characteristic of a waveform, in particular for an arbitrary waveform generator (AWG).

The RF generation module is configured to generate a first phase reference signal and a carrier signal on the basis of the at least one received control variable and to transmit the first phase reference signal to the control module. The carrier signal is preferably a sinusoidal signal. The first phase reference signal is preferably a sinusoidal signal. The reference signal generation module is configured to generate a second phase reference signal and an amplitude reference signal on the basis of the at least one received control variable and to transmit them to the control module.

The control module comprises a phase manipulation unit and an amplitude manipulation unit. The phase manipulation unit comprises a phase detection unit and a phase control unit. The phase detection unit is configured to receive the first phase reference signal and a measured phase signal and to form a phase difference from these signals and transmit it to the phase control unit as a phase difference signal. Such “transmission” takes place in a first operating mode of the phase control unit, which is explained in the following. Such “transmission” is optional in a second operating mode of the phase control unit. The measured phase signal can, for example, originate from an optical phase detection setup by means of a photodiode. In this case, the measured phase signal is an electrical signal that contains the phase information of the optical signal.

A phase control unit is also provided. The phase control unit is configured to receive the phase difference signal and the second phase reference signal in a first operating mode of the phase control unit, to generate a phase control signal therefrom and to transmit the phase control signal to the phase control unit. Therefore, in the first operation mode, the phase control unit operates in a controlled mode to minimize a detected phase deviation (e.g., via the photodiode). The phase control unit is also configured to transmit an adjustable phase control signal, which is independent of the phase difference signal, to the phase control unit in a second operating mode. In the second operating mode, the phase control unit operates in an uncontrolled mode. In this case, a constant value can be specified for the phase control signal, for example in order to be able to observe fluctuations in an optical transmission path. Preferably, the respective first or second operating mode can be selected by a user via the central control module. If a phase control signal is set, this value and optionally a time course of this value can preferably be specified by the user via the central control module.

An amplitude control unit is provided. The amplitude control unit is configured to receive the amplitude reference signal and a measured amplitude signal in a first operating mode of the amplitude control unit and to generate an amplitude control signal therefrom and to transmit the amplitude control signal to the amplitude control unit. The measured amplitude signal can be obtained, for example, by determining an optical power using a photodiode. In this case, the measured amplitude signal is an electrical signal that contains the intensity information of the optical signal. In the first operating mode, the amplitude control unit therefore operates in a controlled mode in order to minimize a detected intensity deviation (e.g. via the photodiode). The amplitude control unit is also configured to transmit an adjustable amplitude control signal that is independent of the measured amplitude signal to the amplitude control unit in a second operating mode. In this case, operation is uncontrolled. In this case, a constant value can be specified for the amplitude control signal in order to be able to observe intensity fluctuations of an optical transmission path, for example. If an amplitude control signal is set, this value and optionally a time course of this value can preferably be specified by the user via the central control module. Preferably, the respective first or second operating mode can be selected by a user via the central control module.

It is easily possible for the first or second operating mode of the phase control unit to be selected independently of the first or second operating mode of the amplitude control unit. The same also applies to the first or second operating mode of the amplitude control unit, which can be selected independently of the selected first or second operating mode of the phase control unit.

The phase control unit is configured to receive the carrier signal and the phase control signal and to generate a phase-manipulated carrier signal therefrom and to transmit the phase-manipulated carrier signal to the amplitude control unit. The carrier signal is manipulated with the aid of the phase control signal. The amplitude control unit is configured to receive the phase-manipulated carrier signal and the amplitude control signal and to generate and output the RF signal from them. This RF signal is preferably used to manipulate, in particular to change the frequency, phase and/or amplitude of an electromagnetic signal, i.e. in particular an optical signal. The RF signal is phase and amplitude modulated (if a corresponding modulation is activated).

Alternatively, the amplitude control unit is configured to receive the carrier signal and the amplitude control signal and to generate an amplitude-manipulated carrier signal therefrom and to transmit the amplitude-manipulated carrier signal to the phase control unit, whereby the phase control unit is configured to receive the amplitude-manipulated carrier signal and the phase control signal and to generate and output the RF signal therefrom. The carrier signal is manipulated with the aid of the amplitude control signal. This RF signal is preferably used to manipulate, in particular to change the frequency, phase and/or amplitude of an electromagnetic signal, i.e. in particular an optical signal. The RF signal is phase and amplitude modulated (if a corresponding modulation is activated).

The versatile RF control system according to the disclosure makes it possible to control all properties of an optical signal with just a single RF signal. The existing control system means that any errors that occur in the optical transmission path can be compensated for very quickly. As the control can be switched on and off at any time, it is possible to compensate for errors in the optical transmission path and to monitor errors occurring in the optical transmission path. Since the RF signal can be set arbitrarily in terms of its properties, modulation can also be applied to the RF signal, for example to perform operations in quantum computers. Without the additional regulation, a modulated RF signal would be subject to errors on the (optical) transmission path that could no longer be compensated for, which would falsify a calculation result, for example when using the versatile RF control system in quantum computers. Only through the use of stabilized and/or controlled modulation of (optical) signals is the repeatable execution of computing operations in quantum computers and the repeatable manipulation of quantum states in quantum systems possible. Due to its design, it is possible to address a wide variety of optical setups and other applications for the manipulation of quantum states in quantum systems with a single RF control system according to the disclosure. This flexible use is particularly advantageous for users when applications change, because the RF control system can then continue to be used directly without replacement.

In an further development of the versatile RF control system, a clock generation module is provided. The clock generation module comprises at least one first clock generation unit, which is configured to generate a first reference clock and output it to the RF generation module of the at least one module group. The RF generation module of the at least one module group is configured to generate the carrier signal and the first phase reference signal using the same first reference clock. The first reference clock can, for example, be an analog sinusoidal signal or a digital square wave signal. The clock generation module can be, for example, a DDS, a VCO or a PLL. By using the first (common) reference clock for generating the carrier signal and the first phase reference signal, there is a deterministic phase relationship between the carrier signal and the first phase reference signal. The clock generation module is also preferably configured to make the first reference clock available to several or all existing module groups. As a result, there is a deterministic phase relationship between the respective carrier signals and the respective first phase reference signals of different module groups.

In an further development of the versatile RF control system, the clock generation module comprises at least one second clock generation unit, which is configured to generate a second reference clock and output it to the reference signal generation module of the at least one module group. The reference signal generation module of the at least one module group is configured to generate the amplitude reference signal and the second phase reference signal using the same second reference clock. The second reference clock can, for example, be an analog sinusoidal signal or a digital square wave signal. The clock generation module can, for example, be configured to generate the second reference clock by dividing the first reference clock with a frequency divider. By using the second (common) reference clock to generate the amplitude reference signal and the second phase reference signal, there is a deterministic phase relationship between the amplitude reference signal and the second phase reference signal. The clock generation module is also preferably configured to make the second reference clock available to several or all existing module groups. As a result, there is a deterministic phase relationship between the respective amplitude reference signals and the respective second phase reference signals of different module groups.

In a further development of the versatile RF control system, the carrier signal and the first phase reference signal of the at least one module group are identical. The term “identical” is to be understood as meaning that the phase and the frequency of the carrier signal do not differ from the phase and the frequency of the first phase reference signal. The carrier signal and the first phase reference signal can therefore be generated by a common signal source (e.g. DDS, DAC), with a power divider splitting the generated signal into the carrier signal and the first phase reference signal. This enables a favorable synthesis with high phase stability. A low power consumption of the RF generation module is also provided in the event that the phase comparison frequency for the phase detection unit corresponds to the frequency of the carrier signal. Optionally, the amplitude of the carrier signal also corresponds to the amplitude of the first phase reference signal. However, the amplitudes of the carrier signal and the first phase reference signal could also be selected differently in order to achieve optimum modulation of the phase detection unit.

In an further development of the versatile RF control system, the carrier signal and the first phase reference signal of the at least one module group are arithmetically linked to one another, with the link relating to frequency, phase and/or amplitude.

In particular, this link can be established via a specification by the central control module. This specification can be made by the user. The arithmetic link can only apply for a certain period of time. An “arithmetic link” means, for example, a defined relationship between the frequency of the carrier signal and the frequency of the first phase reference signal. For example, the optical phase detection setup can be realized in a so-called double-pass configuration, so that the frequency of the measured phase signal corresponds to twice the frequency of the RF signal applied to the modulator. For phase detection, it is therefore necessary to set the phase comparison frequency to twice the frequency of the carrier signal so that the frequency of the first phase reference signal corresponds exactly to twice the frequency of the carrier signal. Modulation parameters would also be scaled accordingly by an arithmetic operation. In such a case, for example, the modulation depth of a frequency modulation would also be doubled, while the modulation frequency would not be doubled. If the RF signal is subjected to a frequency conversion (e.g. by a frequency conversion unit) before being fed to the modulator, this change must be taken into account accordingly when determining the arithmetic operation between the carrier signal and the first phase reference signal.

In an further development of the versatile RF control system, the first phase reference signal and the second phase reference signal of the at least one module group are linked to each other, wherein the link relates to frequency, phase and/or amplitude. The “link” would preferably be formed in such a way that either the first phase reference signal or the second phase reference signal is modulated. Simultaneous application of the modulation parameters to the first phase reference signal and the second phase reference signal would result in no modulated phase control signal being generated in order to finally generate a modulation of the RF signal, because the modulations would cancel each other out within the control loop in the phase control unit. In particular, this link can be established via a specification by the central control module. This specification can be made by the user. The link can only apply for a certain period of time.

In an further development of the versatile RF control system, the reference signal generation module of the at least one module group comprises a reference conditioning unit. The reference conditioning unit is configured to generate the amplitude reference signal from at least a first and a second signal and preferably to output it to the control module, wherein the first signal is different from the second signal. For example, the first signal can have a ramp-shaped curve or approximate a ramp-shaped curve, while the second signal may correspond to a periodically modulated signal. This makes it easier for the user to specify a signal amplitude curve. It is also possible to switch off or change at least one of the signals, while the other signal is still present and does not need to be specified again. In particular, the “specifications” can be a waveform that the reference signal generation module receives via the central control module. The reference conditioning unit can be analog or digital.

In an further development of the versatile RF control system, the phase manipulation unit of the at least one module group comprises the phase control unit, wherein the phase control unit is of analog design, in particular by using an analog phase shifter or a mixer.

In another further development of the versatile RF control system, the RF generation module of the at least one module group comprises the phase adjustment unit, wherein the phase adjustment unit comprises a DSP unit (digital signal processing) and a frequency synthesis unit. Preferably, the necessary phase change is calculated in the DSP unit and transferred to the frequency synthesis unit. For example, the frequency synthesis unit can be realized by a DDS and the DSP would determine a new phase word and transmit it to the DDS.

In a further development of the versatile RF control system, the amplitude manipulation unit of the at least one module group comprises the amplitude control unit, wherein the amplitude control unit is implemented in an analog design, in particular by using at least one amplifier and/or at least one adjustable attenuator. The attenuator can be a VVA, for example. Preferably, the analog design would be selected in order to deteriorate the SNR (signal to noise ratio) as little as possible.

In another further development of the versatile RF control system, the RF generation module of the at least one module group comprises the amplitude control unit, wherein the amplitude control unit comprises a DSP unit and a frequency synthesis unit. The necessary amplitude change is calculated in the DSP unit and transferred to the frequency synthesis unit. For example, the frequency synthesis unit can be realized by a DAC and the DSP unit would determine a new setting word and transmit it to the DAC.

In a further development of the versatile RF control system, the central control module is configured to receive at least one operating parameter. The central control module is configured to control the phase control unit of the at least one module group depending on the received at least one operating parameter in such a way that it operates in the first or second operating mode or changes the operating mode. This “change” can also take place during operation. The central control module is also configured to control the amplitude control unit of the at least one module group depending on the received at least one operating parameter in such a way that it operates in the first or second operating mode or changes the operating mode. This “change” can also take place during operation. The operating parameter can be preset by a user. In the simplest case, the operating parameter can be a digital trigger signal, whereby the first operating mode or the second operating mode is selected depending on the logic state. Changing the operating mode within the amplitude control unit is particularly possible if controlled operation is only required for a short time and the intensity of an optical signal is greatly altered. The resulting temperature changes in the crystalline material of the modulator reduce the maximum achievable optical power. If you switch to uncontrolled operation (second operating mode) when the controlled amplitude control signal is not required, the crystalline modulator can be preheated by applying the resulting RF signal so that the maximum transmittable power of an optical transmission path is increased.

In an further development of the versatile RF control system, the central control module is configured to receive at least one control parameter. The central control module is configured to configure the phase control unit of the at least one module group as a function of the received at least one control parameter such that a controller type of the phase control unit of the at least one module group can be defined from one of a plurality of controller types and/or that a transfer function of the phase control unit of the at least one module group can be defined, which describes a generation of the phase control signal from a difference between the phase difference signal and the second phase reference signal. The controller types may in particular be a selection between a P, PI, PID controller or a related controller type. Preferably, the user can select the desired controller type via an input screen. The transfer function can be determined, for example, by specifying the P gain, the I gain and/or the D gain. Preferably, the user can enter the corresponding transfer function, i.e. the P-gain, the I-gain and/or the D-gain, via an input screen. The central control module is also configured to configure the amplitude control unit of the at least one module group depending on the received at least one control parameter in such a way that a controller type of the amplitude control unit of the at least one module group can be defined from one of several controller types and/or that a transfer function of the amplitude control unit of the at least one module group can be defined, which describes a generation of the amplitude control signal from a difference between the measured amplitude signal and the amplitude reference signal. The controller types can in particular be a selection between a P, PI, PID controller or a related controller type. Preferably, the user can select the desired controller type via an input screen. The transfer function can be determined, for example, by specifying the P gain, the I gain and/or the D gain. Preferably, the user can enter the corresponding transfer function, i.e. the P-gain, the I-gain and/or the D-gain, via an input screen.

In a further development of the versatile RF control system, the amplitude manipulation unit of the at least one module group comprises an amplitude calibration unit. The amplitude calibration unit comprises a first, second and/or third calibration stage. An input signal can be fed to the amplitude calibration unit, the amplitude calibration unit being designed using the first, second and/or third calibration stage to generate and output the measured amplitude signal from the feedable input signal. The first calibration stage is configured to add a first offset value to the supplied input signal in order to shift the supplied input signal. The second calibration stage is configured to amplify an input signal of the second calibration stage. The third calibration stage is configured to add a second offset value to an input signal of the third calibration stage in order to shift the input signal of the third calibration stage. For example, the calibration unit can be realized by an instrumentation amplifier with adjustable gain, as well as a first and a second adjustable voltage source. The input signal to be calibrated is preferably connected to the non-inverting input of the instrumentation amplifier, while the first adjustable voltage source is connected to the inverting input of the instrumentation amplifier. This allows, for example, the dark current of a photodiode, which converts the intensity of the optical signal into an electrical signal, to be compensated and the zero point of the sensor to be calibrated. The sensitivity of the input signal to be calibrated can be adjusted by amplifying the instrumentation amplifier. By using the amplitude calibration unit, differences in the sensitivities of different photodiodes can be compensated once in a simple manner without having to rescale the amplitude reference signals of different module groups in the first operating mode of the amplitude control unit. Finally, the reference potential for the measured amplitude signal can be determined by applying the second adjustable voltage source to the reference node of the instrumentation amplifier. A shift in the reference potential may be necessary in order to exploit an optimized dynamic range of an ADC (analogue digital converter) for digitizing the measured amplitude signal.

In a further development of the versatile RF control system, a first bias tee is provided in the at least one module group. The first bias tee is configured to superimpose a first DC voltage on an incoming phase signal. This allows an operating voltage to be supplied to a photodiode. The first bias tee is also configured to output only an alternating component of the incoming phase signal as a measured phase signal to the phase detection unit, because only the alternating component contains the phase information.

In a further development of the versatile RF control system, the at least one module group comprises a first DC voltage source which is configured to generate the first DC voltage for the first bias tee of the at least one module group and to transmit it to the first bias tee of the at least one module group. This first DC voltage corresponds to the operating voltage of the photodiode. The central control module is configured to receive at least one first bias parameter. The central control module is configured to control the first DC voltage source of the at least one module group as a function of the received first bias parameter in such a way that it generates the desired first DC voltage. The first bias parameter can, for example, be specified by a user. The first DC voltage source can, for example, be a DAC or an adjustable LDO (low dropout regulator).

In a further development of the versatile RF control system, a second bias tee is provided in the at least one module group. The second bias tee is configured to superimpose a second DC voltage on the RF signal. The second bias tee is further configured to output the RF signal superimposed with the second DC voltage. The second DC voltage is used to set the operating point of the (optical) modulator.

In a further development of the versatile RF control system, the at least one module group comprises a second DC voltage source, wherein the second DC voltage source is configured to generate the second DC voltage for the second bias tee of the at least one module group and to transmit it to the second bias tee of the at least one module group. The central control module is configured to receive at least one second bias parameter. The central control module is configured to control the second DC voltage source of the at least one module group as a function of the received second bias parameter in such a way that it generates the desired second DC voltage. The second bias parameter can be specified by a user. The second DC voltage source can, for example, be a DAC or an adjustable LDO (low dropout regulator).

In another further development of the versatile RF control system, the at least one module group comprises a bias point control unit. The bias point regulator unit is configured to receive a bias point reference signal and a measured bias point signal. The bias point control unit is configured to generate the second DC voltage in such a way that the deviation between the bias point reference signal and the measured bias point signal is less than a threshold value. The bias point control unit is configured to transmit the second DC voltage to the second bias tee. Tracking of the second DC voltage by the bias point control unit is necessary, for example, to compensate for temperature-related drifts in the operating point of the (optical) modulator. The bias point control unit can comprise a P, PI or PID controller. A PI controller is preferably used.

In a further development of the versatile RF control system, the at least one module group comprises a frequency conversion unit. The frequency conversion unit is configured to receive a local oscillator signal and the RF signal. The frequency conversion unit is configured to change a frequency of the RF signal by mixing it with the local oscillator signal and then to output the RF signal. In optical applications, such as spectroscopy of atoms, typically only very narrow-band modulations are required, so that the entire signal path does not have to be high-frequency. This saves costs and improves the noise behavior of the frequency-shifted RF signal.

In a further development of the offset RF control system, the frequency conversion unit of the at least one module group comprises a filter unit. The filter unit is configured to select a specific sideband and filter the RF signal in order to then output the RF signal. Frequency conversion by means of a mixer produces at least two sidebands, only one of which is actually used and selected by the filter unit. The filter unit can be implemented using an adjustable bandpass, for example. The central control module is configured to receive at least one parameter in the form of a filter parameter. This filter parameter can be specified by a user. The central control module is configured to feed the filter parameter to the filter unit as a control variable, whereby the adjustable bandpass selects a specific sideband.

In a further development of the versatile RF control system, the versatile RF control system comprises at least one output means, wherein at least one signal of the following group of signals can be output for a user of the versatile RF control system via the at least one output means:
a) the second phase reference signal;
b) the amplitude reference signal;
c) the measured phase signal;
d) the measured amplitude signal;
e) the phase difference signal;
f) a phase error signal between the second phase reference signal and the phase difference signal;
g) an amplitude error signal between the amplitude reference signal and the measured amplitude signal;
h) the phase control signal;
i) the amplitude control signal.

The output of the above signals is serves for monitoring the operation of the RF control system and to detect malfunctions easily and quickly. In addition, these signals can be used to characterize and adjust the RF control system.

In a further development of the versatile RF control system, the at least one output means of the at least one module group is a user display on a screen, a digital signal output and/or an analog signal output. Each signal can, for example, be output on more than one output means simultaneously.

In a further development of the versatile RF control system, the RF generation module, the reference generation module and the control module are each integrated in a separate semiconductor chip or in a common semiconductor chip. This reduces the volume and energy consumption. This serves for improving scalability for multi-channel applications. This may be particularly necessary for quantum computers, which have a high number of qubits. The semiconductor chip can have a CMOS structure, for example.

In a further development of the versatile RF control system, the versatile RF control system comprises a housing. The at least one module group is arranged in a common module frame in the housing of the RF control system. Alternatively, the RF generation module, the reference generation module and the control module of the at least one module group are arranged in at least two or three different module frames in the housing of the RF control system. Defective modules can thus be replaced very easily. At the same time, the versatile RF control system can be easily equipped with the required module groups according to user requirements. Subsequent upgrading or modification of the module groups is also easily possible.

In a further development of the versatile RF control system, the central control module is arranged in a module frame in the housing of the RF control system. Here only one control module is used within the versatile RF control system, which saves costs and installation volume. In addition, the number of external interfaces required is reduced and simpler synchronization across different module groups is possible, whereby latencies for signal transmission are low and essentially constant.

In a further development of the versatile RF control system, the clock generation module is arranged in a module frame in the housing of the RF control system. Here only one clock generation module is used within the versatile RF control system, which saves costs and installation volume. At the same time, the same clock signals are supplied to all modules, even across different module groups. This reduces or avoids unfavorable or disruptive phase drifts between modules, even across different module groups.

In a further development of the versatile RF control system, a backplane is provided for data exchange between different modules in the different module frames. The RF generation module, the reference signal generation module and the control module of the respective module group are connected to the backplane for mutual data exchange. In addition or alternatively, the central control module and/or the clock generation module are connected to the backplane. The backplane is preferably a PCB arrangement. The individual modules of a module group can communicate with each other and also with the central control module via a common interface. The common interface is preferably a broadband communication interface so that large amounts of data can be transmitted in a short time. In particular, the common interface can be PCI Express or PXI Express. Preferably, the individual modules are hot-swappable. The individual modules are preferably also powered via the backplane.

In a further development of the versatile RF control system, a large number of module groups are provided in order to generate and output several RF signals independently of each other. Such a modular structure is supports quantum systems that usually require more than one RF signal source. Because each module group generates a single RF signal independently of another module group, the electrical properties (e.g. frequency, phase, amplitude) of the individual RF signals can be adjusted individually, i.e. independently of each other, precisely according to requirements. Depending on the number of RF signal sources required, the necessary number of module groups is installed in the versatile RF control system. This number can be varied as required due to the modular design.

In a further development of the versatile RF control system, the RF signal can be fed to a quantum system in particular via an antenna and/or a cable arrangement. In this case, no optical signal is manipulated by the generated RF signal. Instead, the RF signal can be used to manipulate quantum states in a quantum system. Non-conducted transmission, in particular via the antenna, may be used e.g., if the quantum system is located in an ultra-high vacuum chamber. This eliminates the need for a line feed into the ultra-high vacuum environment, thereby reducing costs. Conducted feeds, on the other hand, are particularly suitable for quantum systems that are arranged on semiconductor chips.

The optical arrangement according to the disclosure comprises the versatile RF control system and an optical system. The optical system has at least one acousto-optical or electro-optical modulator. The RF signal of the at least one module group generated by the versatile RF control system can be fed as an input signal to an input of the at least one acousto-optical or electro-optical modulator. This allows signal characteristics of the RF signal to be impressed on the optical signal. In particular, the frequency, amplitude and phase of the optical signal can be manipulated.

In a further development of the optical arrangement, a first photodiode is provided, wherein the first photodiode is configured to generate the measured phase signal of the at least one module group indirectly or directly and to transmit it to the phase detection unit of the at least one module group. “Indirect” generation means that further elements are present in the signal path between the first photodiode and the phase detection unit, such as the first bias tee and/or an amplifier unit. The supply voltage of this first photodiode can be set by the first bias tee of the corresponding module group. “Direct” generation means that the signal path between the first photodiode and the phase detection unit is free of further elements. Furthermore, a second photodiode is provided, wherein the second photodiode is configured to generate the measured amplitude signal for the at least one module group and to transmit it directly or indirectly to the amplitude control unit of the at least one module group. An “indirect” transmission means that further elements are present in the signal path between the second photodiode and the amplitude control unit, such as the amplitude calibration unit and/or an amplifier unit. By “direct” transmission it is meant that the signal path between the second photodiode and the amplitude control unit is free of further elements.

In a further development of the optical arrangement, a common photodiode is provided, wherein the common photodiode is configured to generate both the measured phase signal and the measured amplitude signal indirectly or directly and to transmit them to the respective phase detection unit and the respective amplitude control unit of the at least one module group. With regard to “indirect” generation and “direct” generation, reference is made to the above further development. Costs can be saved by using a common photodiode.

In a further development of the optical arrangement, an output of the at least one acousto-optical or electro-optical modulator can be connected to a quantum system. By applying the RF signal to the at least one acousto-optic or electro-optic modulator, quantum states in the quantum system can be manipulated via the optical signal.

The measuring device according to the disclosure has an optical arrangement. The measuring device according to the disclosure is preferably a vector network analyzer, which is configured to be connected to at least one DUT (device under test). The DUT can have only optical interfaces or a mixture of optical and electrical interfaces. The optical arrangement is configured to generate and transmit the optical signal to the interface to the DUT and/or to receive an optical signal from the interface of the DUT. The versatile RF control system within the optical arrangement is configured to generate an RF signal with which a precisely defined modulated optical signal (in terms of frequency, phase, amplitude) can be generated. By means of the amplitude control unit and the phase control unit within the at least one module group of the versatile RF control system, it is possible to adjust (operating mode 2) and/or stabilize (operating mode 1) the modulated optical signal at a defined reference plane with regard to frequency, phase and/or amplitude. The reference plane is preferably located at the transition to the DUT.

The versatile RF control system within the optical compound is configured to determine the phase and amplitude information of the optical signal emitted by the DUT by converting the phase information and amplitude information of the optical signal into an electrical signal. The first photodiode can generate the measured phase signal directly or indirectly from the phase information of the optical signal and transmit it to the phase detection unit. The second photodiode can generate the measured amplitude signal directly or indirectly from the amplitude information of the optical signal and transmit it to the amplitude control unit. Preferably, the measured amplitude signal is generated indirectly by the amplitude calibration unit, which is arranged between the second photodiode and the amplitude control unit in order to enable a system error corrector. Once the corresponding module group of the versatile RF control system is adapted to receive phase information and amplitude information from the DUT, the phase control unit is adapted to enter the second operation mode. Furthermore, in this case, the amplitude control unit is also configured to adopt the second operating mode. In principle, it would also be possible to use the common photodiode to receive the phase and amplitude information of the optical signal emitted by the DUT.

In the following, the disclosure is described purely by way of example with reference to the drawings. It shows:

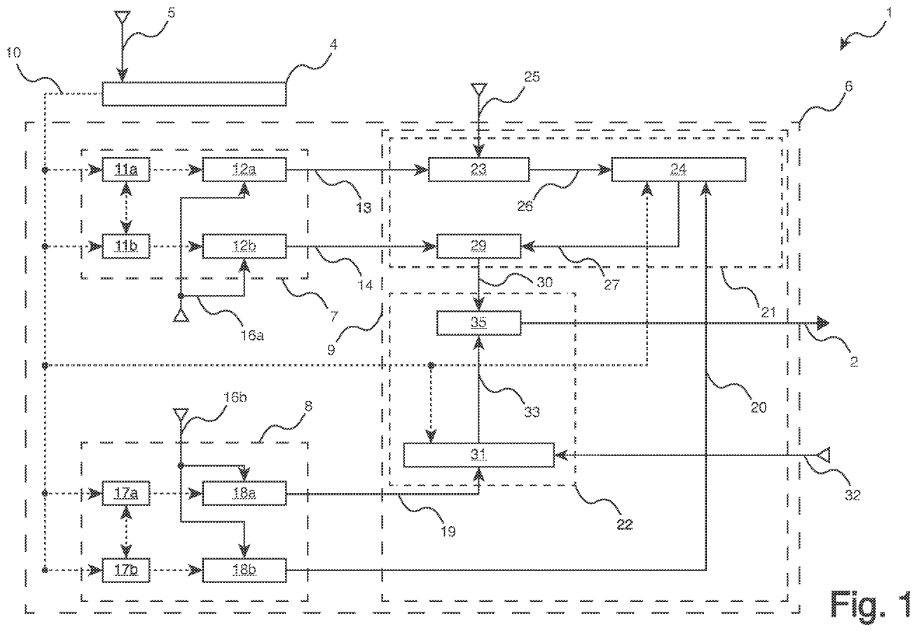

FIGS. 1, 2 and 3:

various embodiments of a versatile RF control system according to the disclosure;

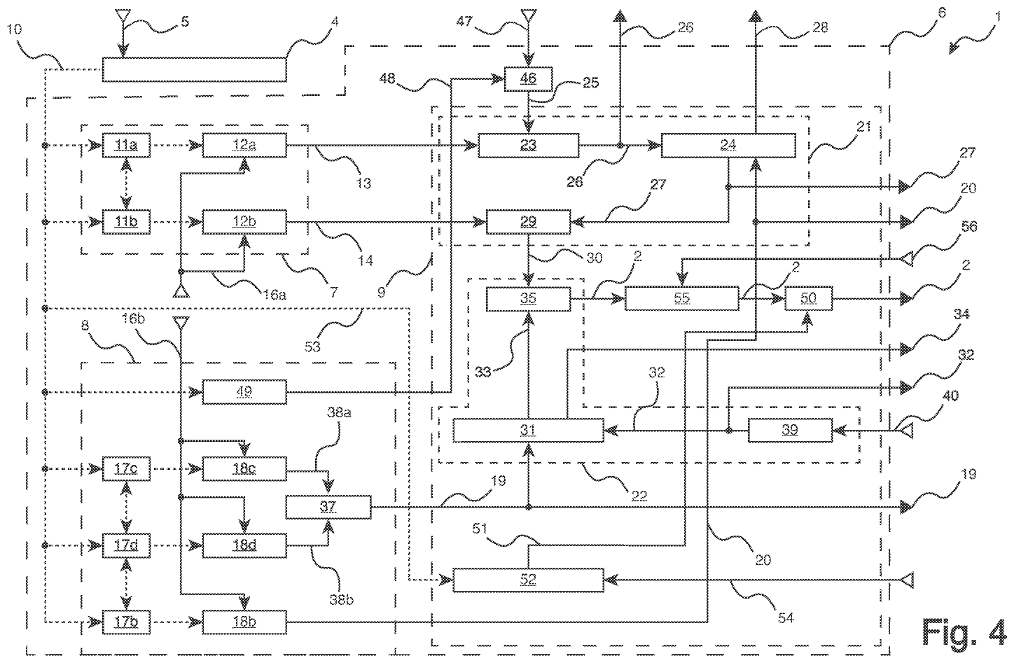

FIG. 4: a further exemplary embodiment of the versatile RF control system according to the disclosure with additional embodiments;

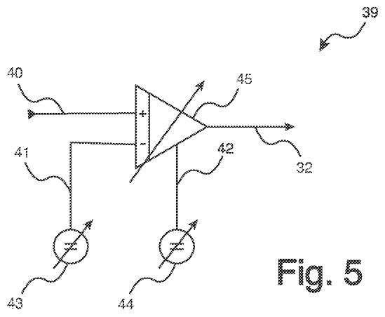

FIG. 5: an exemplary embodiment of an amplitude calibration unit for the versatile RF control system;

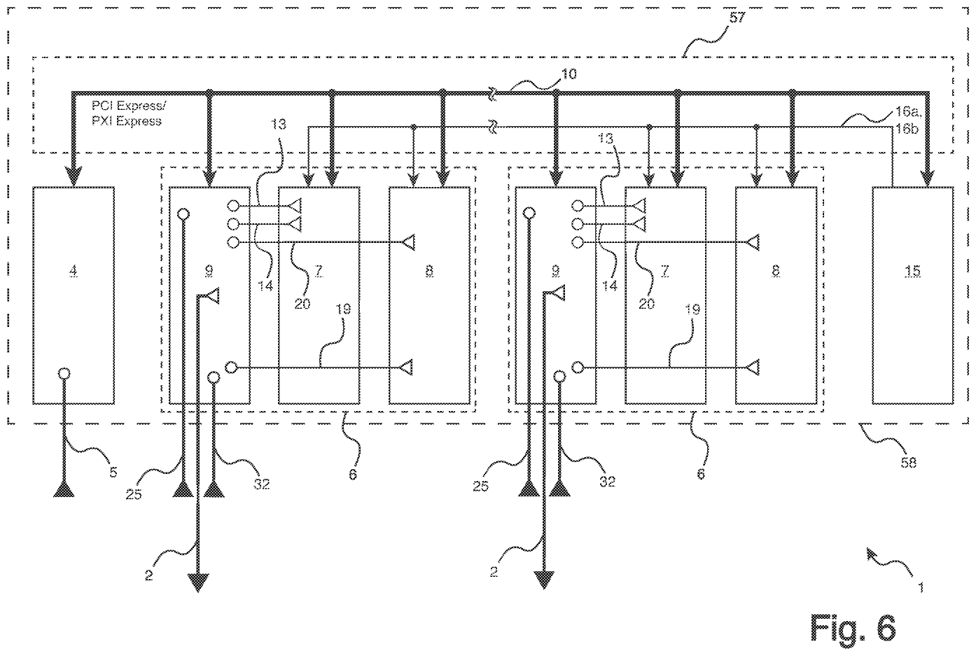

FIG. 6: a further exemplary embodiment of the versatile RF control system with several module groups;

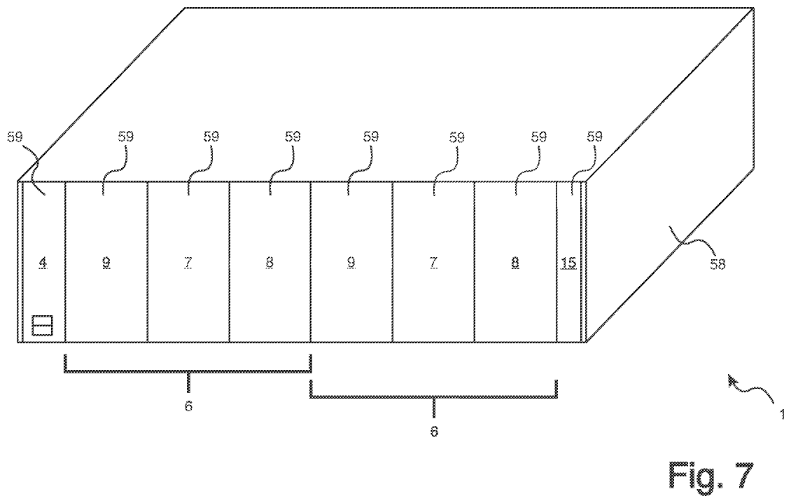

FIG. 7: a spatial representation of the versatile RF control system of FIG. 6; and

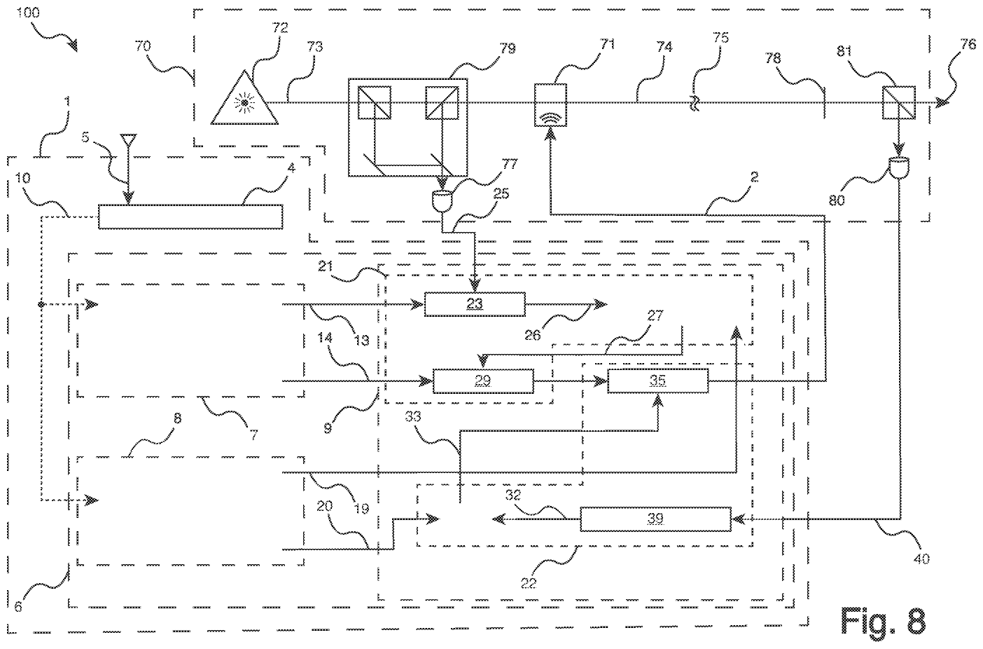

FIG. 8: an exemplary embodiment of the optical arrangement with a versatile RF control system and an optical system.

FIG. 1 shows an exemplary embodiment of the versatile RF control system 1 according to the disclosure. The versatile RF control system 1 can be used in particular to generate an RF signal 2. The RF signal 2 can be used to manipulate an optical signal 73 (see FIG. 8). It is also possible that quantum systems, such as quantum computers, can be controlled via the RF signal 2.

The versatile RF control system 1 has a modular structure in order to be flexibly adapted to the current application. This is explained in detail below.

The versatile RF control system 1 comprises a central control module 4. The central control module 4 can be, for example, a computer, FPGA (field programmable gate array), ASIC (application-specific integrated circuit), DSP and/or microcontroller. For example, an output unit such as a computer screen can be connected to the central control module 4. An output unit is also understood to mean when the central control module 4 generates a web page via which an exchange with a user takes place. The central control module 4 is configured to receive parameters 5. In particular, the parameters 5 are user inputs or specifications that the user makes in order to configure the versatile RF control system 1. For example, the user can use the parameters 5 to specify the frequency, amplitude and phase of the RF signal 2 to be generated and output. This also includes the specification of a corresponding modulation of the RF signal 2.

In addition to the central control module 4, the versatile RF control system 1 comprises at least one module group 6. Preferably, there is a large number of module groups 6, which can be used to expand the versatile RF control system 1. Each module group 6 is configured to generate a corresponding RF signal 2.

The at least one module group 6 comprises an RF generation module 7, a reference signal generation module 8 and a control module 9. In this context, it is emphasized that the use of different modules is merely intended to facilitate the readability and comprehensibility of the description of the versatile RF control system 1. In principle, modules can merge into one another, and digital units in particular can be integrated into a common semiconductor chip such as an FPGA or ASIC.

The central control module 4 is configured to communicate with a large number of module groups 6. A user can communicate with the individual module groups 6 via the central control module 4 in order to configure the RF signals 2 to be output. The central control module 4 is also adapted to communicate with the RF generation module 7, the reference signal generation module 8 and the control module 9 within a module group 6. FIG. 1 shows such a communication interface in dashed lines.

In the figures, digital communication connections are primarily represented by dashed lines, whereas analog signal paths are represented by solid lines.

The central control module 4 is configured to generate control variables 10 for the RF generation module 7 of the at least one module group 6 based on the parameters 5 received (from the user). These control variables 10 can be transmitted to the RF generation module 7. In this case, the control variables 10 can be specifications for the frequency and phase.

The RF generation module 7 comprises, for example, a first DSP unit 11a and a second DSP unit 11b. The RF generation module 7 also comprises a first frequency synthesis unit 12a and a second frequency synthesis unit 12b. The RF generation module 7 is configured to generate a first phase reference signal 13 by means of the first DSP unit 11a and the first frequency synthesis unit 12a. The RF generation module 7 is further configured to generate a carrier signal 14 by means of the second DSP unit 11b and the second frequency synthesis unit 12b. The first DSP unit 11a and the second DSP unit 11b are linked to each other via an interface (arithmetically) in order to be able to exchange data. In particular, this interface is a digital interface. The first DSP unit 11a and the second DSP unit 11b can be realized in a common FPGA or ASIC.

In addition to the central control module 4, the versatile RF control system 1 comprises a (central) clock generation module 15 (see FIGS. 6, 7). The clock generation module 15 is configured to generate and provide clock signals for the individual module groups 6. Preferably, the individual module groups 6 share a clock signal.

In this context, the clock generation module 15 comprises a first clock generation unit (not shown), which is configured to generate a first reference clock 16a and to output it to the RF generation module 7 of the at least one module group 6. The RF generation module 7 of the at least one module group 6 is configured to generate the phase reference signal 13 and the carrier signal 14 using the same first reference clock 16a.

The first frequency synthesis unit 12a and the second frequency synthesis unit 12b may be integrated in a common semiconductor chip or in a common semiconductor chip package.

In principle, it is conceivable that the first phase reference signal 13 and the carrier signal 14 are identical at least in terms of frequency and phase.

The central control module 4 is configured to generate control variables 10 for the reference signal generation module 8 of the at least one module group 6 on the basis of the parameters 5 received (from the user). These control variables 10 can be transmitted to the reference signal generation module 8. In this case, the control variables 10 can be specifications for the signal progression over time.

The reference signal generation module 8 comprises, for example, a first DSP unit 17a and a second DSP unit 17b. The reference signal generation module 8 also comprises a first signal synthesis unit 18a and a second signal synthesis unit 18b. The reference signal generation module 8 is configured to generate an amplitude reference signal 19 by means of the first DSP unit 17a and the first signal synthesis unit 18a. The reference signal generation module 8 is further configured to generate a second phase reference signal 20 by means of the second DSP unit 17a and the second frequency synthesis unit 17b. The first DSP unit 17a and the second DSP unit 17b are linked to one another via an interface in order to be able to exchange data. In particular, this interface is a digital interface. The first DSP unit 17a and the second DSP unit 17b can be realized in a common FPGA or ASIC.

The first signal synthesis unit 18a and the second signal synthesis unit 18b can be integrated in a common semiconductor chip or in a common semiconductor chip housing.

In this context, the clock generation module 15 comprises a second clock generation unit (not shown), which is configured to generate a second reference clock 16b and to output it to the reference signal generation module 8 of the at least one module group 6. The reference signal generation module 8 of the at least one module group 6 is configured to generate the amplitude reference signal 19 and the second phase reference signal 20 using the same second reference clock 16b.

The first DSP unit 11a of the RF generation module 7 and the second DSP unit 17b of the reference signal generation module 8 can also be interconnected via a digital interface, so that the first phase reference signal 13 and the second phase reference signal 20 can be linked to each other, this link relating to frequency, phase and/or amplitude.

The first DSP unit 11a and the second DSP unit 12a of the RF generation module 7 and the first DSP unit 17a and the second DSP unit 17b of the reference signal generation module 8 can be realized in a common semiconductor chip, in particular in a common FPGA or ASIC.

In particular, the control module 9 comprises a phase manipulation unit 21 and an amplitude manipulation unit 22. The phase manipulation unit 21 comprises a phase detection unit 23 and a phase control unit 24.

The phase detection unit 23 is adapted to receive the first phase reference signal 13. The phase detection unit 23 is further configured to receive a measured phase signal 25. The phase detection unit 23 is configured to form a phase difference from the first phase reference signal 13 and the measured phase signal 25 and to transmit this phase difference to the phase control unit 24 as a phase difference signal 26.

The phase control unit 24 is configured to be able to be operated in a first operating mode and in a second operating mode. The respective first or second operating mode can be selected in particular by the central control module 4, wherein the central control module 4 is in turn configured to receive a corresponding parameter 5 from a user, from which the first or second operating mode to be selected is derived. In this case, the parameter 5 comprises at least one operating parameter which indicates which operating mode is to be selected.

In the first operating mode, the phase control unit 24 is configured to receive the phase difference signal 26 and the second phase reference signal 20 and to generate a phase control signal 27 therefrom.

The central control module 4 is also configured to receive in addition to a parameter, in particular in the form of at least one operating parameter, another parameter, in particular in the form of at least one control parameter. This at least one control parameter can also be entered by the user and thus specified. By means of the at least one control parameter, the phase control unit 24 can be configured differently with regard to its mode of operation in the first operating mode. Preferably, the controller type of the phase control unit 24 can be selected from a group of several controller types depending on the at least one control parameter. In addition or alternatively, a transfer function can be selectable from a group of transfer functions or a transfer function can be defined, wherein the transfer function describes the generation of the phase control signal 27 from a difference between the phase difference signal 26 and the second phase reference signal 20. The difference can also be referred to as the phase error signal 28 (see FIG. 4).

When the phase control unit 24 is in the second operating mode, the phase control unit 24 is adapted to output a phase control signal 27 which is independent of the phase difference signal 26. In this case, the phase control signal 27 to be output can be received by the central control module 4 via a control variable 10. The central control module 4 is in turn configured to receive the phase control signal 27 to be output from the user via a parameter 5. It is also possible that the phase control signal 27 to be output is stored in a memory unit within the phase control unit 24. The memory unit may, for example, be part of a DAC.

It is again emphasized that it is possible to switch back and forth between the first operating mode and the second operating mode of the phase control unit 24 during operation of the versatile RF control system 1. In particular, the switching back and forth can take place more than 1 time per minute, 10 times, 50 times, 100 times, 500 times or more than 1000 times per minute.

It is also emphasized that, for example, the phase detection unit 23 and the phase control unit 24 may be integrated in a common unit.

The phase control signal 27 can be transmitted to a phase setting unit 29 by the phase control unit 24. The phase setting unit 29 is configured to receive the carrier signal 14 and the phase control signal 27 and to generate a phase-manipulated carrier signal 30 therefrom. The phase manipulation is performed by the phase setting unit 29 as a function of the phase control signal 27.

The amplitude manipulation unit 22 comprises an amplitude control unit 31. The amplitude control unit 31 is configured to be operable in a first operating mode and in a second operating mode. The respective first or second operating mode can be selected in particular by the central control module 4, wherein the central control module 4 is in turn configured to receive a corresponding parameter 5 from a user, from which the first or second operating mode to be selected is derived. In this case, the parameter 5 comprises at least one operating parameter which indicates which operating mode is to be selected.

In the first operating mode, the amplitude control unit 31 is configured to receive the amplitude reference signal 19 and a measured amplitude signal 32 and to generate an amplitude control signal 33 therefrom.

The central control module 4 is also configured to receive in addition to a parameter, in particular in the form of the at least one operating parameter, another parameter, in particular in the form of at least one control parameter. This at least one control parameter can also be entered by the user and thus specified. The at least one control parameter allows the amplitude control unit 31 to be configured differently with regard to its mode of operation in the first operating mode. Preferably, the controller type of the amplitude control unit 31 can be selected from a group of several controller types depending on the at least one control parameter. In addition or alternatively, a transfer function can be selectable from a group of transfer functions or a transfer function can be defined, wherein the transfer function describes the generation of the amplitude control signal 33 from a difference between the measured amplitude signal 32 and the amplitude reference signal 19. The difference can also be referred to as the amplitude error signal 34 (see FIG. 4).

When the amplitude control unit 31 is in the second operating mode, the amplitude control unit 31 is adapted to output an amplitude control signal 33 which is independent of the measured amplitude signal 32. In this case, the amplitude control signal 33 to be output can be received by the central control module 4 via a control variable 10. The central control module 4 is in turn configured to receive the amplitude control signal 33 to be output from the user via a parameter 5. It is also possible that the amplitude control signal 33 to be output is stored in a memory unit within the amplitude control unit 31. The memory unit may, for example, be part of a DAC.

It is again emphasized that it is possible to switch back and forth between the first operating mode and the second operating mode of the amplitude control unit 31 during operation of the versatile RF control system 1. In particular, the switching back and forth can occur more than 1 time per minute, 10 times, 50 times, 100 times, 500 times or more than 1000 times per minute.

It is also emphasized that, for example, the amplitude control unit 31, the phase detection unit 23 and the phase control unit 24 may be integrated in a common unit. The phase detection unit 23, the phase control unit 24, the phase setting unit 29 and/or the amplitude control unit 31 may be constructed with analog and/or digital components.

The amplitude control signal 33 can be transmitted to an amplitude setting unit 35 by the amplitude control unit 31. The amplitude setting unit 35 is configured to receive the phase-manipulated carrier signal 30 from the phase setting unit 29 and the amplitude control signal 33 from the amplitude control unit 31 and to generate and output the RF signal 2 therefrom. The amplitude is set by the amplitude setting unit 35 depending on the amplitude control signal 33.

According to FIG. 1, the phase manipulation unit 21 also comprises the phase setting unit 29, whereby the phase setting unit 29 in this case has an analog design, in particular by using an analog phase shifter or a mixer.

According to FIG. 1, the amplitude manipulation device 22 additionally also comprises the amplitude setting unit 35, the amplitude setting unit 35 being of analog design, in particular by using at least one amplifier and/or adjustable attenuator.

The phase manipulation device 21 and the amplitude manipulation unit 22 are preferably of analog design in FIG. 1. They can be integrated into a common device. In particular, the phase manipulation unit 21 and the amplitude manipulation unit 22 are arranged on a common printed circuit board arrangement, the common printed circuit board arrangement preferably comprising exactly one printed circuit board.

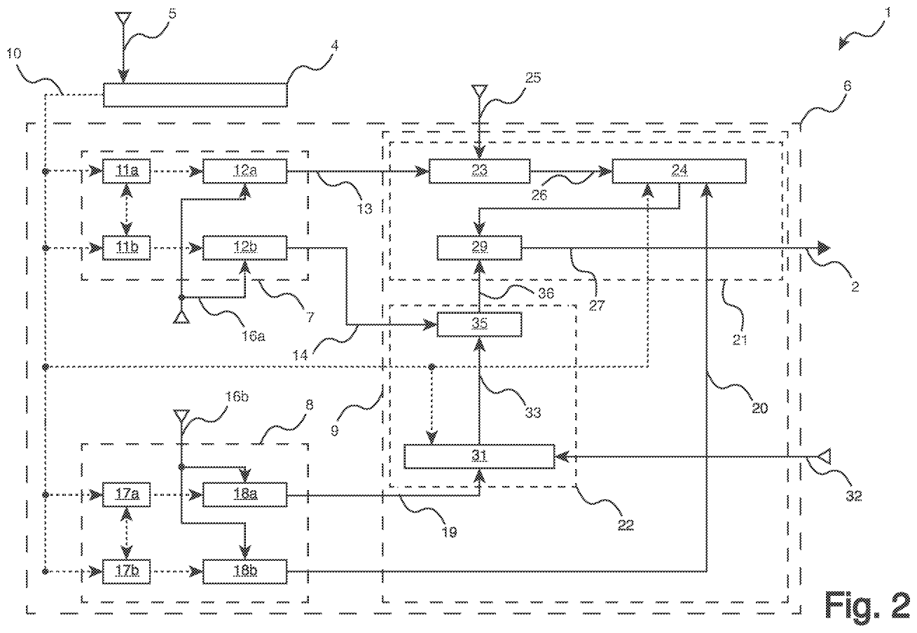

FIG. 2 shows a further exemplary embodiment of the versatile RF control system 1 according to the disclosure. In contrast to the exemplary embodiment in FIG. 1, in FIG. 2 the phase setting unit 29 is configured to generate and output the RF signal 2. In this case, the amplitude setting unit 35 is configured to receive the carrier signal 14 and to generate an amplitude-manipulated carrier signal 36 therefrom and to transmit the amplitude-manipulated carrier signal 36 to the phase setting unit 29. The amplitude manipulation of the carrier signal 14 takes place in the amplitude setting unit 35 using the amplitude control signal 33. The phase setting unit 29 is configured to receive the amplitude-manipulated carrier signal 36 and the phase control signal 27 and to generate and output the RF signal 2 therefrom. The phase setting unit 29 is configured to manipulate the phase of the amplitude-manipulated carrier signal 36 as a function of the phase control signal 27, whereby the RF signal 2 is generated.

In a further exemplary embodiment not shown, it would be conceivable that the amplitude setting unit 35 is arranged in the RF generation module 7. The second DSP unit 11b of the RF generation module 7 can be configured to receive the amplitude control signal 33 and to control the second frequency synthesis unit 12b in such a way that it directly transmits the amplitude-manipulated carrier signal 36 to the phase setting unit 29. In this case, the amplitude manipulation unit 22 would comprise only the amplitude control unit 31, the amplitude manipulation unit preferably operating digitally. In this case, the reference generation module 8 will not require the first signal synthesizing unit 18a, so that the amplitude reference signal 19 is directly generated by the first DSP unit 17a of the reference generation module 8 and transmitted to the amplitude control unit 31. The amplitude control unit could also be integrated in the first DSP unit 17a of the reference generation module 8, with the measured amplitude signal 32 further being supplied to the first DSP unit 17a of the reference generation module 8.

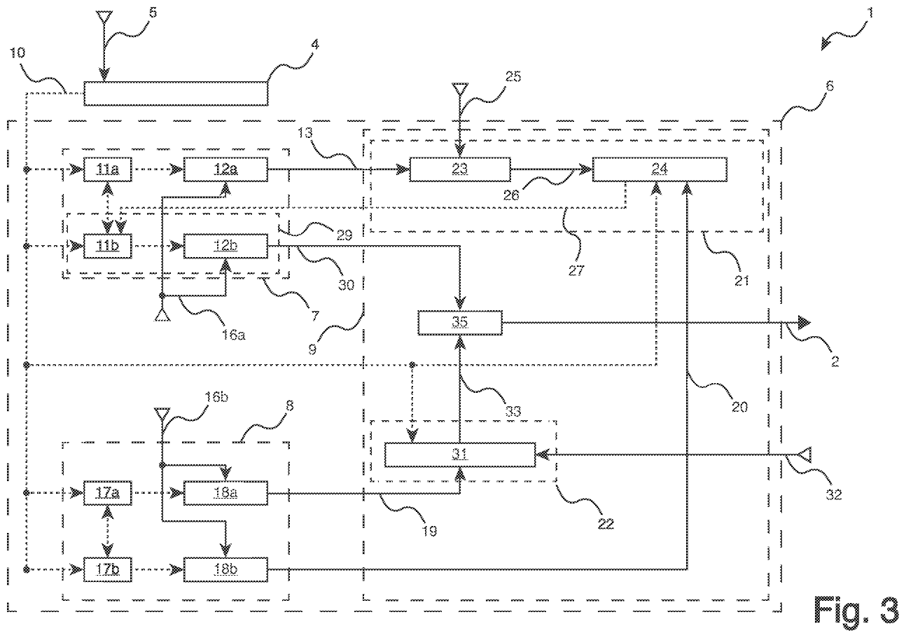

FIG. 3 shows a further exemplary embodiment of the versatile RF control system 1 according to the disclosure. In contrast to the exemplary embodiment in FIG. 1, the RF generation module 7 comprises the phase setting unit 29. The phase setting unit 29 comprises a DSP unit, which is in particular the second DSP unit 11b of the RF generation module 7. The phase setting unit 29 also comprises a frequency synthesis unit, which is in particular the second frequency synthesis unit 12b of the RF generation module 7. The second DSP unit 11b of the RF generation module 7 can be configured to receive the phase control signal 27 and to control the second frequency synthesis unit 12b in such a way that it directly generates the phase-manipulated carrier signal 30 and transmits it to the amplitude setting unit 35. In this case, the phase manipulation unit 21 would only comprise the phase detection unit 23 and the phase control unit 24.

In principle, it would also be conceivable that the RF generation module 7 further comprises the amplitude setting unit 35, wherein the amplitude setting unit 35 comprises a DSP unit, which is in particular the second DSP unit 11b of the RF generation module 7, and wherein the amplitude setting unit 35 comprises a frequency synthesis unit, which is in particular the second frequency synthesis unit 12b of the RF generation module 7. In this case, the amplitude control unit 31 would transmit the amplitude control signal 33 to the RF generation module 7 and, in particular, directly to the second DSP unit 11b of the RF generation module 7. The second frequency synthesis unit 12b of the RF generation module 7 would then be configured to output an amplitude-manipulated and phase-manipulated carrier signal, which is the RF signal 2. Further, this RF signal 2 would preferably be fed to at least one amplifier and/or at least one adjustable attenuator.

FIG. 4 shows a further embodiment of the versatile RF control system 1 according to the disclosure with additional embodiments.

The reference signal generation module 8 comprises a reference conditioning unit 37. The reference conditioning unit 37 is configured to generate the amplitude reference signal 19 from at least a first signal 38a and a second signal 38b. The first signal 38a and the second signal 38b are different from each other. The reference generation module 8 comprises a third signal synthesis unit 18c for generating the first signal 38a. Furthermore, the reference generation module 8 comprises a fourth signal synthesis unit 18d for generating the second signal 38b. The reference generation module 8 further comprises a third DSP unit 17c, wherein the third DSP unit 17c is adapted to generate a waveform for the first signal 38a and to drive the third signal synthesis unit 18c such that the third signal synthesis unit 18c outputs the first signal 38a. The reference generation module 8 further comprises a fourth DSP unit 17d, wherein the fourth DSP unit 17d is adapted to generate a waveform for the second signal 38b and to drive the fourth signal synthesis unit 18d such that the fourth signal synthesis unit 18d outputs the second signal 38b.

Furthermore, it is shown that the amplitude manipulation unit 22 of the at least one module group 6 of the versatile RF control system 1 comprises an amplitude calibration unit 39.

A possible exemplary embodiment of the amplitude calibration unit 39 is shown in FIG. 5.

The amplitude calibration unit 39 comprises a first, second and/or third calibration stage. An input signal 40 can be fed to the amplitude calibration unit 39, wherein the amplitude calibration unit 39 is designed using the first, second and/or third calibration stage to generate and output the measured amplitude signal 32 from the feedable input signal. The first calibration stage is configured to add a first offset value 41 to the supplied input signal 40 in order to shift the supplied input signal 40. The second calibration stage is configured to amplify an input signal of the second calibration stage. The third calibration stage is configured to add a second offset value 42 to an input signal of the third calibration stage in order to shift the input signal of the third calibration stage.

A first adjustable voltage source 43 is provided to generate the first offset value 41. A second adjustable voltage source 44 is provided to generate the second offset value 42. The first and second adjustable voltage sources 43, 44 are preferably arranged on the control module 9 or the reference signal generation module 8. The central control module 4 is configured to receive parameters 5, in particular in the form of voltage parameters, from a user and to adjust the first and second adjustable voltage sources 43, 44 in accordance with the voltage parameters. The first and second adjustable voltage sources 43, 44 are preferably realized in the form of a DAC.

The second calibration stage preferably comprises an instrumentation amplifier 45. The input signal 40 to be calibrated is preferably connected to the non-inverting input of the instrumentation amplifier 45, while the first adjustable voltage source 43 is connected to the inverting input of the instrumentation amplifier 45. The gain of the instrumentation amplifier 45 is adjustable. This adjustment can again be made by a user, whereby the central control module 4 is configured to receive a parameter 5 in the form of a gain parameter and to control the instrumentation amplifier 45 in such a way that it provides the desired gain.

The amplitude calibration unit 39 can be constructed using analog components and/or digitally operating components.

Furthermore, FIG. 4 shows that the at least one module group 6 of the versatile RF control system 1 comprises a first bias tee 46. The first bias tee 46 is configured to superimpose a first DC voltage 48 on an incoming phase signal 47. The first bias tee 46 is further configured to output only an alternating portion of the incoming phase signal 47 as a measured phase signal 25 to the phase detection unit 23. The first bias tee 46 may be arranged outside the control module 9 or in the control module 9.

The at least one module group 6 comprises a first DC voltage source 49, which is configured to generate the first DC voltage 48 for the first bias tee 46 of the at least one module group 6 and to transmit it to the first bias tee 46 of the at least one module group 6. The central control module 4 is configured to receive at least one parameter 5, in the form of a first bias parameter. This first bias parameter can be specified by a user. The central control module 4 is configured to supply the first bias parameter as a control variable 10 to the first DC voltage source 49. The first DC voltage source 49 is configured to adjust the first DC voltage 48 as a function of the received control variable 10.

Preferably, the second reference clock 16b, which is generated by the clock generation module 15, is present at the second, third and fourth signal synthesis units 18b, 18c and 18d. Further preferably, the second reference clock 16b, which is generated by the clock generation module 15, is present at all components within the reference signal generation module 8 that require an external clock signal.

Furthermore, it is shown that the at least one module group 6 of the versatile RF control system 1 comprises a second bias tee 50. The second bias tee 50 is configured to superimpose a second DC voltage 51 on the RF signal 2. The second bias tee 50 is further configured to output the RF signal 2 superimposed with the second DC voltage 51.

Not shown is that the at least one module group 6 in one exemplary embodiment comprises a second DC voltage source, which is configured to generate the second DC voltage 51 for the second bias tee 50 of the at least one module group 6 and to transmit it to the second bias tee 50 of the at least one module group 6. The central control module 4 is configured to receive at least one parameter 5, in the form of a second bias parameter. This second bias parameter can be specified by a user. The central control module 4 is configured to feed the second bias parameter to the second DC voltage source as a control variable 10. The second DC voltage source is configured to adjust the second DC voltage 51 as a function of the received control variable 10.

Instead of using the second DC voltage source, the exemplary embodiment in FIG. 4 suggests that the at least one module group 6 has a bias point control unit 52. The bias point control unit 52 is configured to receive a bias point reference signal 53 and a measured bias point signal 54. The central control module 4 is configured to receive at least one parameter 5 in the form of a bias reference parameter. This bias reference parameter can be specified by a user. The central control module 4 is configured to supply the bias reference parameter to the bias point control unit 52 as a control variable 10, i.e. as the bias point reference signal 53. The bias point control unit 52 is configured to generate the second DC voltage 51 in such a way that the deviation between the bias point reference signal 53 and the measured bias point signal 54 is smaller than a threshold value, in particular an adjustable or predetermined threshold value. The bias point control unit 52 is then configured to transmit the second DC voltage 51 to the second bias tee 50.

Furthermore, it is shown that the at least one module group 6 of the versatile RF control system 1 has at least one frequency conversion unit 55. The frequency conversion unit 55 is configured to receive a local oscillator signal 56 and the RF signal 2. The frequency conversion unit 55 is further configured to change a frequency of the RF signal 2 by mixing it with the local oscillator signal 56 and then to output the RF signal 2.

It is not shown that the frequency conversion unit 55 also comprises a filter unit. The filter unit is configured to select a specific sideband and to filter the RF signal 2 in order to subsequently output the RF signal 2. The filter unit can, for example, be implemented using an adjustable bandpass filter. The central control module 4 is configured to receive at least one parameter 5 in the form of a filter parameter. This filter parameter can be specified by a user. The central control module 4 is configured to feed the filter parameter to the filter unit as a control variable 10, whereby the adjustable bandpass selects a specific sideband.

It is also shown that the versatile RF control system 1 and in particular the at least one module group 6 allows the user access to a large number of signals. A large number of output means are provided for this purpose. The output means can be, for example, a user display on a screen, a digital signal output and/or an analog signal output. In FIG. 4, the second phase reference signal 20, the amplitude reference signal 19, the measured amplitude signal 32, the phase difference signal 26, the phase error signal 28, the amplitude error signal 34 and the phase control signal 27 can be supplied to corresponding output means. It is not shown that the measured phase signal 25 and the amplitude control signal 33 are also fed to corresponding output means.

FIG. 6 shows a further exemplary embodiment of the versatile RF control system 1 with several module groups 6. It can be seen that the RF control system 1 can be extended by any number of module groups 6. FIG. 6 shows that the RF control system 1 comprises two module groups 6, with each module group 6 comprising an RF generation module 7, a reference generation module 8 and a control module 9. Furthermore, the versatile RF control system 1 comprises a central control module 4 and a clock generation module 15. The central control module 4 is configured to receive user input in the form of parameters 5. The RF generation module 7 of the respective module group 6 is configured to generate the first phase reference signal 13 and the carrier signal 14 and, in this exemplary embodiment, to transmit them to the control module 9 of the respective module group 6. The reference generation module 8 of the respective module group 6 is configured to generate the amplitude reference signal 19 and the second phase reference signal 20 and, in this exemplary embodiment, to transmit them to the control module 9 of the respective module group 6. The control module 9 of the respective module group 6 is configured to output the RF signal 2 and to receive the measured phase signal 25 and the measured amplitude signal 32. A measured phase signal 25 and a measured amplitude signal 32 are therefore received for each module group 6. These signals 25, 32 of course differ from module group 6 to module group 6. Control variables 10 can, for example, be transmitted directly from the central control module 4 to each module group 6 and within each module group 6 to each individual module 7, 8, 9 of this module group 6.

A backplane 57 is also provided for data exchange. The RF generation module 7, the reference signal generation module 8 and the control module 9 of the respective module group are connected to the backplane for mutual data exchange. The central control module 4 and a clock generation module 15 are also connected to the backplane 57. The first reference clock 16a and the second reference clock 16b, which are generated by the clock generation module 15, can therefore be supplied to the RF generation module 7 and the reference signal generation module 8 in the respective module group 6 via the backplane 57.

It is further shown that the versatile RF control system 4 comprises a housing 58. In particular, the central control module 4, the clock generation module 15 and the respective module groups 6 with the corresponding RF generation module 7, the reference signal generation module 8 and the control module 9 are arranged in the housing 58.

It is also conceivable that there is at least one power supply module (not shown), which can be used to supply power to the central control module 4, the clock generation module 15 and the respective module groups 6. The power supply module can also be connected to the backplane 57, so that the power supply takes place via the backplane 57. The power supply module can be arranged on the same side of the backplane 57 as the central control module 4, the clock generation module 15 and the respective module groups 6. However, the power supply module can also be arranged on a rear side of the backplane 57. In principle, it would be conceivable that there is exactly one power supply module for each module 4, 7, 8, 9, 15. In this case, the corresponding module 4, 7, 8, 9, 15 with its respective power supply module could be arranged opposite each other (on different sides of the backplane 57) in relation to the backplane 57.

FIG. 7 shows a spatial representation of the versatile RF control system 1 from FIG. 6. The housing 58 of the versatile RF control system 1 can be seen. It is also shown that the central control module 4 is arranged in a module frame 59. The central control module 4 can be inserted into the housing 58 of the versatile RF control system 1 via this module frame 59. The clock generation module 15 is also arranged in a module frame 59. The clock generation module 15 can be inserted into the housing 58 of the versatile RF control system 1 via this module frame 59.

The RF generation module 7, the reference signal generation module 8 and the control module 9 are also (each) arranged in a separate module frame 59. The RF generation module 7, the reference signal generation module 8 and the control module 9 can be inserted into the housing 58 of the versatile RF control system 1 via these module frames 59.

The module frames 59 can have the same or a different width. FIG. 7 shows that the module frames 59 for the RF generation module 7, the reference signal generation module 8 and the control module 9 have the same width.

It is also conceivable that at least two or all modules 7, 8, 9 from the group of the RF generation module 7, the reference signal generation module 8 and the control module 9 are accommodated in a common module frame 59.

Preferably, the data exchange of digital data between the central control module 4 and the clock generation module 15, as well as between the individual modules 7, 8, 9 of the respective module group 6, takes place only via the backplane 57.

An exchange of analog data between the modules 7, 8, 9 of a module group 6 preferably takes place at the module front via corresponding cables and/or brackets.

In a preferred embodiment, data between modules 7, 8, 9 of a module group 6, which are arranged in different module frames 59, is only transmitted as digital data between these modules 7, 8, 9 via the backplane 57. This means that these modules 7, 8, 9 can be inserted into the housing 58 of the versatile RF control system 1 at any position and in any number. The central control module 4 is then configured to form various module groups 6, whereby the central control module 4 selects the necessary modules 7, 8, 9 for a module group 6 from the available modules 7, 8, 9. If a module 7, 8, 9 fails, the corresponding housing frame 59 with the defective module 7, 8, 9 can simply be pulled out of the housing 58. If a module 7, 8, 9 fails, the central control module 4 is immediately able to allocate a corresponding replacement module 7, 8, 9 from unused modules 7, 8, 9 and assign it to the module group 6.

The central control module 4 can also be configured to indicate a defect in a module 7, 8, 9 by a corresponding display means, in particular in the form of an LED, on the corresponding module 7, 8, 9.

The parameters 5, which the central control module 4 can receive, can in particular be operating parameters, control parameters, voltage parameters, gain parameters, first bias parameters, second bias parameters, bias reference parameters, filter parameters. For these parameters 5, the central control module 4 can generate corresponding control variables 10 and transmit them to the respective module group 6 or the respective module 7, 8, 9 within the module group 6.

It is also emphasized that different units, devices and modules can be combined and that the isolated representation was chosen here in particular for the sake of a better overview. In particular, an assignment of a unit or device to a specific module may deviate from the assignment shown here. The type of assignment chosen should not be understood as a limitation.

FIG. 8 shows an exemplary embodiment of the optical arrangement 100 with the versatile RF control system 1 and an optical system 70. For the sake of clarity, not all components of the versatile RF control system 1 that have already been described are shown in the illustration of FIG. 8, although these are of course present in the actual embodiment.

The optical system 70 comprises at least one acousto-optical or electro-optical modulator 71. The RF signal 2 of the at least one module group 6 can be fed as an input signal to an input of the at least one acousto-optical or electro-optical modulator 71.

The optical system 70 comprises an optical signal source 72 in order to be able to generate at least one optical signal 73. The optical signal source 72 is preferably a laser. The optical signal 73 can be fed to the acousto-optical or electro-optical modulator 71. The acousto-optical or electro-optical modulator 71 is configured to imprint the characteristics of the RF signal 2 on the optical signal 73 and output it as a modulated optical signal 74. After passing through an optical transmission path 75, the modulated optical signal can be fed to a receiver (not shown) as a useful optical signal 76. As already explained at the beginning, the optical useful signal 76 can differ from the modulated optical signal 74 in terms of its properties because the transmission path 75 can imprint undesirable errors on the modulated optical signal 74. In order to be able to compensate for these unwanted errors, phase errors in the useful optical signal 76 are detected via a first photodiode 77. For this purpose, the useful optical signal 76 is partially reflected back in the direction of the optical signal source 72 by a mirror arrangement 78 in the vicinity of the receiver. A first optical decoupling arrangement 79 is provided between the optical signal source 72 and the acousto-optical or electro-optical modulator 71. The first optical decoupling arrangement 79 is configured to decouple the optical signal 73 (running in the forward direction), which is generated by the optical signal source 72, and the reflected part of the useful optical signal 76 (running in the reverse direction) and to superimpose them on one another and feed them to the first photodiode 77. The first photodiode 77 is configured to generate the measured phase signal 25 of the at least one module group 6 indirectly or directly and to transmit it to the phase detection unit 23 of the at least one module group 6. The supply voltage (first DC voltage 48) of the first photodiode 77 can, for example, be ensured by the first bias tee 46. The phase information of the optical useful signal 76 is preferably converted into the (electrical) measured phase signal 25 by an optical heterodyne method using the first photodiode 77. When the first bias tee 46 is used, the measured phase signal 25 is still superimposed by the supply voltage (first DC voltage 48) and is present as a pure alternating signal at the output of the first bias tee 46 at the phase detection unit 23.

Furthermore, in order to be able to compensate for these undesirable errors (e.g. transmission errors), intensity errors in the optical useful signal 76 are detected via a second photodiode 80. A second optical decoupling arrangement 81 is provided in the vicinity of the receiver. The second optical decoupling arrangement 81 is configured to decouple a portion of the useful optical signal 76 and feed it to the second photodiode 80, wherein the second photodiode 80 is configured to convert the portion of the useful optical signal 76 fed to it into the measured amplitude signal 32. The second photodiode 80 is further configured to generate the measured amplitude signal 32 for the at least one module group 6 and to transmit it directly or indirectly to the amplitude control unit 31 of the at least one module group 6.

The disclosure is not limited to the described embodiments. Within the scope of the disclosure, all described and/or drawn features can be combined with each other as desired.

### LIST OF REFERENCE SYMBOLS

Versatile RF control system 1
HF signal 2
Central control module 4
Parameter 5
Module group 6
RF generation module 7
Reference signal generation module 8
Control module 9
Control variables 10
First DSP unit 11a
Second DSP unit 11b
First frequency synthesis unit 12a
Second frequency synthesis unit 12b
First phase reference signal 13
Carrier signal 14
Clock generation module 15
First reference clock 16a
Second reference clock 16b
First DSP unit 17a
Second DSP unit 17b
Third DSP unit 17c
Fourth DSP unit 17d
First signal synthesis unit 18a
Second signal synthesis unit 18b
Third signal synthesis unit 18c
Fourth signal synthesis unit 18d
Amplitude reference signal 19
Second phase reference signal 20
Phase manipulation unit 21
Amplitude manipulation unit 22
Phase detection unit 23
Phase control unit 24
Measured phase signal 25
Phase difference signal 26
Phase control signal 27
Phase error signal 28
Phase setting unit 29
Phase-manipulated carrier signal 30
Amplitude control unit 31
Measured amplitude signal 32
Amplitude control signal 33
Amplitude error signal 34
Amplitude setting unit 35
Amplitude-manipulated carrier signal 36
Reference conditioning unit 37
First signal 38a
Second signal 38b
Amplitude calibration unit 39
Input signal 40
First offset value 41
Second offset value 42
First adjustable voltage source 43
Second adjustable voltage source 44
Instrumentation amplifier 45
First bias tee 46
Incoming phase signal 47
First DC voltage 48
First DC voltage source 49
Second bias tee 50
Second DC voltage 51
Bias point control unit 52
Bias point reference signal 53
Measured bias point signal 54
Frequency conversion unit 55
Local oscillator signal 56
Backplane 57
Housing 58
Housing frame 59
Optical system 70
Modulator 71
Optical signal source 72
Optical signal 73
Modulated optical signal 74
Optical transmission path 75
Optical useful signal 76
First photodiode 77
Mirror arrangement 78
First optical decoupling arrangement 79
Second photodiode 80
Second optical decoupling arrangement 81
Optical compound 100

1. A versatile RF control system comprising a central control module and at least one module group, wherein the at least one module group is used especially for generating an RF signal for manipulating optical signals or for controlling quantum systems, wherein the at least one module group comprises an RF generation module, a reference signal generation module and a control module,
wherein the central control module comprises the following features:
the central control module is configured to receive parameters for the RF signal of the at least one module group that is to be generated;
the central control module is configured to use the received parameters to set control variables for:
a) the RF generation module of the at least one module group and to transmit them to the RF generation module of the at least one module group; and
b) the reference signal generation module of the at least one module group and to transmit them to the reference signal generation module of the at least one module group;
wherein the at least one module group comprises the following features:
the RF generation module is configured to generate, using the at least one received control variable:
a) a first phase reference signal; and
b) a carrier signal;
and to transmit the first phase reference signal to the control module;
the reference signal generation module is configured to generate, on the basis of the at least one received control variable
a) a second phase reference signal; and
b) an amplitude reference signal;
and transmit it to the control module;
the control module comprises a phase manipulation unit and an amplitude manipulation unit;
the phase manipulation unit comprises a:
a) phase detection unit;
b) phase control unit;
the phase detection unit is adapted to receive the first phase reference signal and a measured phase signal and to form a phase difference and transmit it as a phase difference signal to the phase control unit;
wherein a phase setting unit and an amplitude setting unit is provided;
wherein the phase setting unit is configured to generate and output the RF signal, or wherein the amplitude setting unit is configured to generate and output the RF signal.

2. The versatile RF control system according to claim 1, characterized by the following feature:
a clock generation module is provided;
the clock generation module comprises at least one first clock generation unit, which is configured to generate a first reference clock and to output it to the RF generation module of the at least one module group;
the RF generation module of the at least one module group is adapted to generate the carrier signal and the first phase reference signal using the same first reference clock.

3. The versatile RF control system according to claim 2, characterized by the following feature:
the clock generation module comprises at least one second clock generation unit adapted to generate and output a second reference clock to the reference signal generation module of the at least one module group;
the reference signal generation module of the at least one module group is adapted to generate the amplitude reference signal and the second phase reference signal using the same second reference clock.

4. The versatile RF control system according to claim 1, characterized in that the at least one module group comprises the following feature:
the carrier signal and the first phase reference signal are identical.

5. The versatile RF control system according to claim 1, characterized in that the at least one module group comprises the following feature:
the carrier signal and the first phase reference signal are arithmetically linked to each other, wherein the link relates to frequency, phase and/or amplitude.

6. The versatile RF control system according to claim 1, characterized in that the at least one module group comprises the following feature:
the first phase reference signal and the second phase reference signal are linked to each other, wherein the link relates to frequency, phase and/or amplitude.

7. The versatile RF control system according to claim 1, characterized in that the at least one module group comprises the following features:
the reference signal generation module comprises a reference conditioning unit;
the reference conditioning unit is adapted to generate the amplitude reference signal from at least a first signal and a second signal, wherein the first signal and the second signal are different.

8. The versatile RF control system according to claim 1, characterized in that the at least one module group comprises the following feature:
the phase manipulation unit comprises the phase setting unit, wherein the phase setting unit is of analog design, in particular by using an analog phase shifter or a mixer.

9. The versatile RF control system according to claim 1, characterized in that the at least one module group comprises the following feature:
the RF generation module comprises the phase setting unit, wherein the phase setting unit comprises a DSP unit and a frequency synthesis unit.

10. The versatile RF control system according to claim 1, characterized in that the at least one module group comprises the following feature:
the amplitude manipulation unit comprises the amplitude setting unit, wherein the amplitude setting unit is realized in an analog design, in particular by using at least one amplifier and/or at least one adjustable attenuator.

11. The versatile RF control system according to claim 1, characterized in that the at least one module group comprises the following feature:
the RF generation module comprises the amplitude setting unit, wherein the amplitude setting unit comprises a DSP unit and a frequency synthesis unit.

12. The versatile RF control system according to claim 1, characterized by the following features:
the central control module is adapted to receive at least one operating parameter;
the central control module is configured, depending on the received at least one operating parameter:
a) to control the phase control unit of the at least one module group in such a way that it operates in the first or second operating mode or changes the operating mode;
b) to control the amplitude control unit of the at least one module group in such a way that it operates in the first or second operating mode or changes the operating mode.

13. The versatile RF control system according to claim 1, characterized by the following features:
the central control module is adapted to receive at least one control parameter;
the central control module is configured to configure the phase control unit of the at least one module group as a function of the received at least one control parameter in such a way that at least one of:
a) a controller type of the phase control unit of the at least one module group can be defined from one of a plurality of controller types; or
b) a transfer function of the phase control unit of the at least one module group can be defined, which describes a generation of the phase control signal from a difference between the phase difference signal and the second phase reference signal;
the central control module is configured to configure the amplitude control unit of the at least one module group as a function of the received at least one control parameter in such a way that at least one of:
a) a controller type of the amplitude control unit of the at least one module group (6) can be defined from one of a plurality of controller types; or
b) a transfer function of the amplitude control unit of the at least one module group (6) can be defined, which describes a generation of the amplitude control signal from a difference between the measured amplitude signal and amplitude reference signal.

14. The versatile RF control system according to claim 1, characterized in that the at least one module group comprises the following features:
the amplitude manipulation unit comprises an amplitude calibration unit;
the amplitude calibration unit comprises a first, second and/or third calibration stage;
an input signal can be fed to the amplitude calibration unit, the amplitude calibration unit being designed, using the first, second and/or third calibration stage, to generate and output the measured amplitude signal from the feedable input signal, wherein
a) the first calibration stage is configured to add a first offset value to the supplied input signal in order to shift the supplied input signal;
b) the second calibration stage is configured to amplify an input signal of the second calibration stage;
c) the third calibration stage is adapted to add a second offset value to an input signal of the third calibration stage in order to shift the input signal of the third calibration stage.

15. The versatile RF control system according to claim 1, characterized in that the at least one module group comprises the following features:
a first bias tee is provided;
the first bias tee is configured to superimpose a first DC voltage on an incoming phase signal;
the first bias tee is further configured to output only an alternating component of the incoming phase signal as a measured phase signal to the phase detection unit.

16. The versatile RF control system according to claim 15, characterized by the following features:
the at least one module group comprises a first DC voltage source adapted to generate the first DC voltage for the first bias tee of the at least one module group and to transmit it to the first bias tee of the at least one module group;
the central control module is configured to receive at least one first bias parameter;
the central control module is configured to control the first DC voltage source of the at least one module group as a function of the received first bias parameter in such a way that it generates the desired first DC voltage.

17. The versatile RF control system according to claim 1, characterized in that the at least one module group comprises the following features:
a second bias tee is provided;
the second bias tee is configured to superimpose a second DC voltage on the RF signal;
the second bias tee is further configured to output the RF signal superimposed with the second DC voltage.

18. The versatile RF control system according to claim 17, characterized by the following features:
the at least one module group comprises a second DC voltage source adapted to generate the second DC voltage for the second bias tee of the at least one module group and to transmit it to the second bias tee of the at least one module group;
the central control module is configured to receive at least one second bias parameter;
the central control module is configured to control the second DC voltage source of the at least one module group as a function of the received second bias parameter in such a way that it generates the desired second DC voltage.

19. The versatile RF control system according to claim 17, characterized in that the at least one module group comprises the following features:
a bias point control unit is provided;
the bias point control unit is adapted to receive a bias point reference signal and a measured bias point signal;
the bias point control unit is adapted to generate the second DC voltage such that the deviation between the bias point reference signal and the measured bias point signal is less than a threshold value;
the bias point control unit is configured to transmit the second DC voltage to the second bias tee.

20. The versatile RF control system according to claim 1, characterized in that the at least one module group comprises the following features:
a frequency conversion unit is provided;
the frequency conversion unit is configured to receive a local oscillator signal and the RF signal;
the frequency conversion unit is configured to change a frequency of the RF signal by mixing it with the local oscillator signal and then to output the RF signal.

21. The versatile RF control system according to claim 20, characterized in that the at least one module group comprises the following features:
the frequency conversion unit comprises a filter unit;
the filter unit is adapted to select a specific sideband and to filter the RF signal to thereafter output the RF signal.

22. The versatile RF control system according to claim 1, characterized in that the at least one module group comprises the following features:
the versatile RF control system comprises at least one output means, wherein at least one signal of the following group of signals can be output for a user of the versatile RF control system via the at least one output means:
a) the second phase reference signal;
b) the amplitude reference signal;
c) the measured phase signal;
d) the measured amplitude signal;
e) the phase difference signal;
f) a phase error signal between the second phase reference signal and the phase difference signal;
g) an amplitude error signal between the amplitude reference signal and the measured amplitude signal;
h) the phase control signal;
i) the amplitude control signal.

23. The versatile RF control system according to claim 22, characterized in that the at least one module group comprises the following feature:
the at least one output means is at least one of:
a) a user display on a screen;
b) a digital signal output; or
c) an analog signal output.

24. The versatile RF control system according to claim 1, characterized in that the at least one module group comprises the following feature:
the RF generation module, the reference generation module and the control module are each integrated in a separate semiconductor chip or in a common semiconductor chip.

25. The versatile RF control system according to claim 1, characterized by the following feature:
the versatile RF control system comprises a housing;
the at least one module group is arranged in a common module frame in the housing of the RF control system; or
the RF generation module, the reference generation module and the control module of the at least one module group are arranged in at least two or three different module frames in the housing of the RF control system.

26. The versatile RF control system according to claim 25, characterized by the following feature:
the central control module is arranged in a module frame in the housing of the RF control system.

27. The versatile RF control system according to claim 2, characterized by the following features:
the clock generation module is arranged in a module frame in the housing of the RF control system.

28. The versatile RF control system according to claim 25, characterized by the following feature:
a backplane for data exchange is provided, wherein at least one of:
a) the RF generation module, the reference signal generation module and the control module of the respective module group; and/or
b) the central control module; or
c) a clock generation module;
are connected to the backplane for mutual data exchange.

29. The versatile RF control system according to claim 25, characterized by the following feature:
a plurality of module groups are provided to generate and output a plurality of RF signals independently of each other.

30. The versatile RF control system according to claim 1, characterized by the following feature:
the RF signal can be fed to a quantum system, in particular via an antenna and/or a cable arrangement.

31. An optical arrangement comprising a versatile RF control system according to claim 1 and an optical system, wherein the optical system comprises at least one acousto-optical or electro-optical modulator and wherein the RF signal of the at least one module group can be fed as an input signal to an input of the at least one acousto-optical or electro-optical modulator.

32. The optical arrangement according to claim 31, characterized by the following features:
a first photodiode is provided, the first photodiode being configured to generate the measured phase signal of the at least one module group indirectly or directly and to transmit it to the phase detection unit of the at least one module group;
a second photodiode is provided, the second photodiode being configured to generate the measured amplitude signal for the at least one module group and to transmit it directly or indirectly to the amplitude control unit of the at least one module group.

33. The optical arrangement according to claim 31, characterized by the following feature:
a common photodiode is provided, wherein the common photodiode is adapted to indirectly or directly generate and transmit both the measured phase signal and the measured amplitude signal to the respective phase detection unit and the respective amplitude control unit of the at least one module group.

34. The optical arrangement (100) according to claim 31, characterized by the following feature:
an output of the at least one acousto-optic or electro-optic modulator connectable to a quantum system.

35. A measuring device comprising an optical arrangement according to claim 31.

36. The versatile RF control system according to claim 1, wherein
the phase control unit is configured to:
a) in a first operating mode of the phase control unit, receive the phase difference signal and the second phase reference signal and generate a phase control signal therefrom and transmit the phase control signal to the phase setting unit;
b) in a second operating mode of the phase control unit, to transmit an adjustable phase control signal which is independent of the phase difference signal to the phase setting unit;
the amplitude manipulation unit comprises an amplitude control unit;
the amplitude control unit is adapted to:
a) in a first operating mode of the amplitude control unit, receive the amplitude reference signal and a measured amplitude signal and generate an amplitude control signal therefrom and transmit the amplitude control signal to the amplitude setting unit;
b) in a second operating mode of the amplitude control unit, to transmit an adjustable amplitude control signal, which is independent of the measured amplitude signal, to the amplitude setting unit;
and wherein
a) the phase setting unit is configured to receive the carrier signal and the phase control signal and to generate a phase-manipulated carrier signal therefrom and to transmit the phase-manipulated carrier signal to the amplitude setting unit,
wherein the amplitude setting unit is configured to receive the phase-manipulated carrier signal and the amplitude control signal and to generate and output the RF signal therefrom; or
b) the amplitude setting unit is configured to receive the carrier signal and the amplitude adjusting signal and to generate an amplitude-manipulated carrier signal therefrom and to transmit the amplitude-manipulated carrier signal to the phase setting unit, wherein the phase setting unit is configured to receive the amplitude-manipulated carrier signal and the phase control signal and to generate and output the RF signal therefrom.

37. A versatile RF control system comprising a central control module and at least one module group, wherein the at least one module group is used, for example, for generating an RF signal for manipulating optical signals or for controlling quantum systems, and comprises an RF generation module, a reference signal generation module and a control module,
wherein the central control module comprises the following features:
the central control module is configured to receive parameters for the RF signal of the at least one module group that is to be generated;
the central control module is configured to use the received parameters to set control variables for:
a) the RF generation module of the at least one module group and to transmit them to the RF generation module of the at least one module group; and
b) the reference signal generation module of the at least one module group and to transmit them to the reference signal generation module of the at least one module group;
the at least one module group comprises the following features:
the RF generation module is configured to generate, using the at least one received control variable:
a) a first phase reference signal; and
b) a carrier signal;
and to transmit the first phase reference signal to the control module;
the reference signal generation module is configured to generate, on the basis of the at least one received control variable:
a) a second phase reference signal; and
b) an amplitude reference signal;
and transmit it to the control module;
the control module comprises a phase manipulation unit and an amplitude manipulation unit;
the phase manipulation unit comprises a:
a) phase detection unit; and
b) phase control unit;
the phase detection unit is adapted to receive the first phase reference signal and a measured phase signal and to form a phase difference and transmit it as a phase difference signal to the phase control unit;
a phase setting unit is provided;
the phase control unit is configured to:
a) in a first operating mode of the phase control unit, receive the phase difference signal and the second phase reference signal and generate a phase control signal therefrom and transmit the phase control signal to the phase setting unit;
b) in a second operating mode of the phase control unit, to transmit an adjustable phase control signal which is independent of the phase difference signal to the phase setting unit;
the amplitude manipulation unit comprises an amplitude control unit;
an amplitude setting unit is provided;
the amplitude control unit is adapted to:
a) in a first operating mode of the amplitude control unit, receive the amplitude reference signal and a measured amplitude signal and generate an amplitude control signal therefrom and transmit the amplitude control signal to the amplitude setting unit;
b) in a second operating mode of the amplitude control unit, to transmit an adjustable amplitude control signal, which is independent of the measured amplitude signal, to the amplitude setting unit;
and wherein
a) the phase setting unit is configured to receive the carrier signal and the phase control signal and to generate a phase-manipulated carrier signal therefrom and to transmit the phase-manipulated carrier signal to the amplitude setting unit, wherein
the amplitude setting unit is configured to receive the phase-manipulated carrier signal and the amplitude control signal and to generate and output the RF signal therefrom; or
b) the amplitude setting unit is configured to receive the carrier signal and the amplitude adjusting signal and to generate an amplitude-manipulated carrier signal therefrom and to transmit the amplitude-manipulated carrier signal to the phase setting unit,
wherein the phase setting unit is configured to receive the amplitude-manipulated carrier signal and the phase control signal and to generate and output the RF signal therefrom.
